(19) United States
(12) Patent Application Publication
(10) Pub. No.: US 2026/0068731 A1
(43) Pub. Date: Mar. 5, 2026

(54) METHOD OF MANUFACTURING AN ELECTRONIC DEVICE

(71) Applicant: STMicroelectronics International N.V., Geneva (CH)

(72) Inventor: Romain COFFY, Voiron (FR)

(73) Assignee: STMicroelectronics International N.V., Geneva (CH)

(21) Appl. No.: 19/305,147

(22) Filed: Aug. 20, 2025

(30) Foreign Application Priority Data
Aug. 30, 2024 (FR) FR2409283

(51) Int. Cl. H01L 23/00; H01L 25/065

(52) U.S. Cl. CPC H01L 24/13

(57) ABSTRACT

A method includes: providing a support substrate covered by a separation layer, a seed layer, a resin layer having openings; forming, through the openings, interconnection elements by depositing a solder layer, a copper pillar, and optionally a gold layer; removing the resin, and etching the non-covered portion of the seed layer; assembling the interconnection elements to an assembly comprising a substrate in which are formed first chips and second chips assembled to the first chips; wherein the interconnection elements are assembled by thermocompression onto conductive landing areas positioned on the substrate coupled to the first chips; and removing the temporary support and the separation layer.

### PRIORITY CLAIM

This application claims the priority benefit of French Application for Patent No. FR2409283, filed on Aug. 30, 2024, the content of which is hereby incorporated by reference in its entirety to the maximum extent allowable by law.

### TECHNICAL FIELD

The present disclosure generally concerns the field of electronic devices and, in particular, electronic devices comprising chips assembled by direct bonding to substrates (Die-to-Wafer (D2 W)) and their integration on external devices by a so-called “flip-chip” transfer technique.

### BACKGROUND

In a Die-to-Wafer (D2 W) heterogeneous integration, the active surface of an upper chip is assembled by hybrid bonding to the active surface of a lower chip formed in a substrate. To be able to assemble these devices on an external element, such as a printed circuit board, by a so-called flip-chip transfer technique, it is necessary to be able to form interconnection elements (pillars or solder bumps) on connection areas arranged on the substrate and connected to the lower chip.

To have the highest possible density of interconnection elements, pillars are preferred to solder bumps formed by ball jetting.

The pillars, made of copper, are conventionally formed by implementing a photolithography method followed by an electroplating method. For example, the method of forming the pillars may comprise the steps of: providing an assembly comprising the substrate in which are formed the lower chips assembled by hybrid bonding to the upper chips; forming a Ti or TiCu seed layer on the connection areas positioned on the substrate; forming a resist having openings facing the connection areas; electroplating on the seed layer, through the openings of the resist, copper pillars, and then depositing an alloy, for example of SnAgCu (SAC); and removing the resin.

Instead of the resin, it is also possible to deposit a polyimide layer, which will then be kept.

However, the presence of the hybridized upper chips creates a topography (typically from 20 to 30 μm), which prevents pillars from being formed less than 500 μm away from the edges of the upper chips, which strongly limits the density of interconnects that can be formed on an external element. Topography is also a problem for the forming of solder bumps.

There exists a need to have electronic components comprising a substrate in which is formed a chip and on which is mounted another chip, for example by means of a die-to-wafer (D2 W) bonding method, the electronic components having to be able to be assembled with a high density to external elements, typically printed circuit boards, by a so-called flip-chip transfer technique.

### SUMMARY

In an embodiment, a method of manufacturing electronic devices comprises the following steps: a) on a temporary substrate comprising a support substrate successively covered by a separation layer and by a seed layer, forming a resin layer having openings; b) successively depositing through the openings of the resin layer: a solder layer, a copper pillar, and optionally a gold layer, whereby interconnection elements are formed; c) removing the resin layer, and etching the portion of the seed layer not covered by the interconnection elements; d) assembling the interconnection elements to an assembly comprising a substrate in which are formed first chips and second chips assembled to the first chips by hybrid bonding; wherein the interconnection elements are assembled by thermocompression onto conductive landing areas positioned on the support substrate and coupled to the first chips; e) removing the temporary support and the separation layer; and f) preferably carrying out a thermal treatment to melt the solder layer and the seed layer and form solder pads.

According to an embodiment, the temporary support is made of glass or of metal and/or the separation layer is made of an adhesive material sensitive to temperature or to an ultraviolet radiation.

According to an embodiment, the interconnection elements are positioned less than 250 μm away, preferably less than 100 μm away, from the edge of the second chips.

According to an embodiment, the thermocompression step is carried out in the presence of ultrasounds.

According to an embodiment, after step f), the method comprises a step during which the substrate is cut to form individualized electronic devices.

This object is achieved by an assembly comprising a substrate in which are formed first chips, second chips being assembled to the first chips, for example by hybrid bonding; interconnection elements being assembled on conductive landing areas positioned on the substrate and coupled to the first chips, by means of a thermocompressed bond, for example, a copper-to-copper bond or a copper-to-gold bond, the interconnection elements successively comprising from the thermocompressed bond: optionally a gold layer, a copper pillar, and a solder pad; the interconnection elements being positioned less than 250 μm away, preferably less than 100 μm away, and even more preferably less than 50 μm away, from the edge of the second chips.

In an embodiment, an electronic device comprises: a substrate in which is formed a first chip, a second chip being assembled to the first chip, for example by hybrid bonding; interconnection elements being assembled on conductive landing areas positioned on the substrate and coupled to the first chip, by means of a thermocompressed bond, for example a copper-to-copper bond or a copper-to-gold bond; the interconnection elements successively comprising from the thermocompressed bond: optionally a gold layer, a copper pillar, and a solder pad; the interconnection elements being positioned less than 250 μm away, preferably less than 100 μm away, and even more preferably less than 50 μm away, from the edge of the second chips.

According to a specific embodiment, the height of the interconnection elements is in the range from 60 to 80 μm and the diameter of the interconnection elements is in the range from 30 to 50 μm, preferably from 40 to 50 μm.

In an embodiment, an assembly comprises a device such as previously defined and an external device, such as a printed circuit board or a laminated substrate, comprising connection landing areas, the interconnection elements being assembled on the connection landing areas.

In an embodiment, a method of manufacturing an assembly such as previously defined comprises: a step during which the interconnection elements are assembled to the connection landing areas of the external device, for example during a solder step.

### BRIEF DESCRIPTION OF THE DRAWINGS

The foregoing features and advantages, as well as others, will be described in detail in the rest of the disclosure of specific embodiments given as an illustration and not limitation with reference to the accompanying drawings, in which:

FIGS. 1A to 1I schematically show different steps of a method of manufacturing D2 W-type electronic devices at the scale of a substrate according to a specific embodiment;

FIGS. 2A to 2I schematically show different steps of a method of manufacturing D2 W-type electronic devices at the scale of a substrate according to a specific embodiment; and

FIG. 3 and FIG. 4 are simplified representations, in side view and in cross-section, of different assemblies comprising an electronic device and a printed circuit board, according to different specific embodiments.

### DETAILED DESCRIPTION

Like features have been designated by like references in the various figures. In particular, the structural and/or functional features that are common among the various embodiments may have the same references and may dispose identical structural, dimensional and material properties.

The different elements in the drawings are not necessarily shown at a uniform scale to make them more readable.

For clarity, only those steps and elements which are useful to the understanding of the described embodiments have been shown and are described in detail.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following description, where reference is made to absolute position qualifiers, such as “front”, “back”, “top”, “bottom”, “left”, “right”, etc., or relative position qualifiers, such as “top”, “bottom”, “upper”, “lower”, etc., or orientation qualifiers, such as “horizontal”, “vertical”, etc., reference is made unless otherwise specified to the orientation of the drawings in a normal position of use.

Unless specified otherwise, the expressions “about”, “approximately”, “substantially”, and “in the order of” signify plus or minus 10%, preferably of plus or minus 5%.

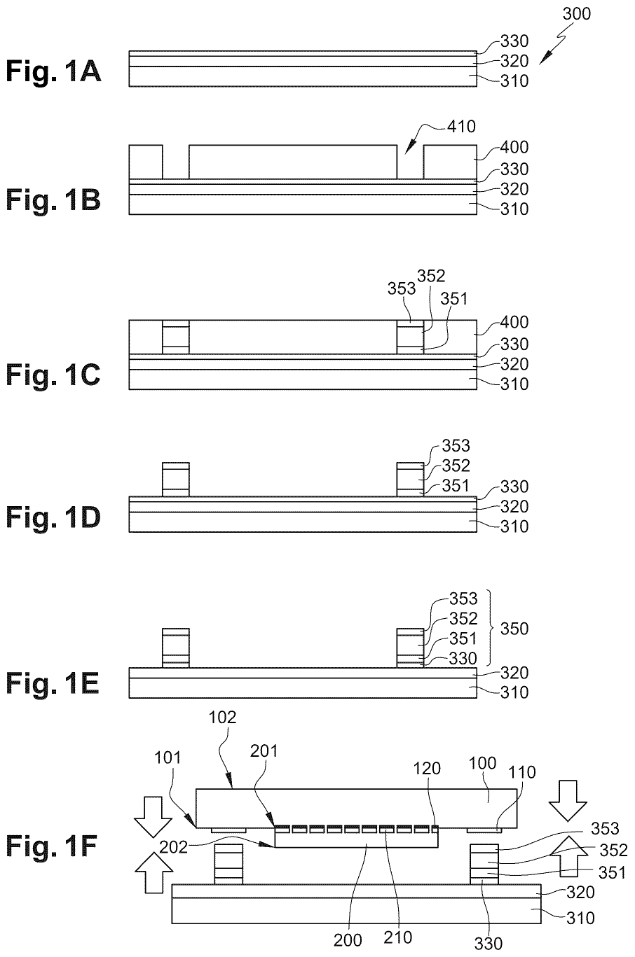

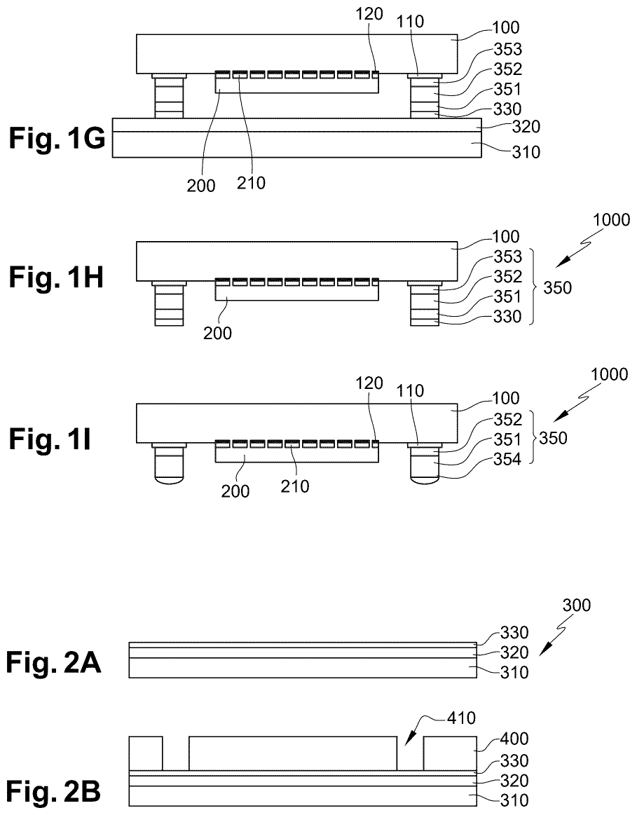

There will now be described in detail the method of manufacturing interconnections of electronic devices, referring to FIGS. 1A to 1I as well as FIGS. 2A to 2I.

The method is described for the manufacturing of electronic devices at the scale of a substrate (‘wafer’). However, it could also be implemented at the scale of individual electronic devices.

The method of manufacturing electronic devices 1000 comprises the following steps: a) on a temporary substrate 300 comprising a support substrate 310 successively covered by a separation layer 320, preferably made of an adhesive material, and by a seed layer 330, forming a resin layer 400 having openings 401 (FIGS. 1A, 1B, and 2A, 2B); b) forming, on seed layer 330, interconnection elements 350, by successively depositing through the openings 401 of resin layer 400, a layer made of a solder alloy 351, a copper pillar 352, and optionally a gold layer 353 (FIGS. 1C and 2C); c) removing resin 400, and etching the portion of seed layer 330 not covered by interconnection elements 350 (FIGS. 1D, 1E, and 1D, 1E); d) assembling interconnection elements 350 to an assembly comprising a substrate 100 in which are formed first chips, second chips 200 being assembled to the first chips, for example by hybrid bonding; interconnection elements 350 being assembled by thermocompression on conductive landing areas 110 positioned on substrate 100 and coupled to the first chips (FIGS. 1F, 1G, and 2F, 2G); e) removing support substrate 310 and separation layer 320 (FIGS. 1H, 2H), for example by applying a thermal treatment or ultraviolet radiation so as to decrease the adhesive properties of separation layer 320; f) preferably implementing a thermal treatment to melt solder layer 351 and seed layer 330 and form solder pads 354 (FIGS. 1I and 2I).

The interconnection elements 350 of electronic devices 1000 are first formed on a temporary substrate 300, after which they are transferred to the connection areas 110 of substrate 100, on which they are assembled by thermocompression. During the thermocompression step, thermocompressed copper-to-copper bonds or thermocompressed copper-to-gold bonds are formed, thus ensuring the mechanical strength of the assembly.

The obtained interconnects are coplanar.

The temporary substrate 300 provided at step a) comprises a support substrate 310 successively covered by a separation layer 320 and by a seed layer 330.

Support substrate 310 is, for example, made of glass or of metal.

Separation layer 320 is, for example, made of an adhesive material sensitive to temperature or to ultraviolet radiation. By sensitive to temperature or to ultraviolet radiation, there is meant that when a thermal treatment or an ultraviolet radiation is applied to the adhesive material, its adhesive properties decrease, thus enabling to separate it from the elements to which it was previously bonded. Preferably, it is an adhesive material sensitive to ultraviolet radiation.

A seed layer 330 covers separation layer 320. Seed layer 330 is electrically conductive and enables to grow pillars 350 by electrodeposition. The seed layer is made of a material selected to be able to be dissolved in the solder alloy. Seed layer 310 is, for example, made of TiCu.

During step a), a resin layer 400 having openings 401 is formed on temporary substrate 300. The resin is, for example, a photoresist. Conventional photolithography techniques may be used to form resin layer 400 exhibiting openings 401.

The positioning of openings 401 in resin layer 400 is selected so that, during the transfer of interconnection elements 350, they are positioned opposite the conductive landing areas 110 of substrate 100.

The height of resin layer 400 is preferably greater than the desired height of interconnection elements 350. The upper portion 151 of interconnection elements 350 is thus well defined. The surface area of openings 401 corresponds to the surface area of interconnection elements 350.

During step b), the interconnection elements are formed in the openings 401 of resin 400. Interconnection elements 350 are formed by successively depositing on seed layer 330, by electrolytic growth: a layer made of a solder alloy 351, a copper pillar 352, and optionally a gold layer 353.

The layer made of a solder alloy 351 may be made of tin or of a tin-based alloy, for example of a SnAgCu alloy (SAC). Layer 351 has, for example, a thickness in the range from 10 to 40 μm.

Copper pillars 352 have, for example, a height in the range from 20 to 60 μm. Gold layer 353 has, for example, a thickness in the range from 1 to 5 μm.

Copper pillars 352 or the assembly formed by gold layer 353 and copper pillars 352 have a height greater than the height of the second chips 200. They have, for example, a height greater than 50 μm.

The interconnection elements 350 are preferably circular. They may have a diameter between 30 and 50 μm, for example a 40-μm diameter.

The dimensions of interconnection elements 350 may be adapted according to the desired pitch size and/or density.

During step c), resin 400 is removed (FIGS. 1D, 2D).

The seed layer 330 non-covered by interconnection elements 350 is then removed (FIGS. 1E, 2E). It may be removed by an etch step.

During step d), interconnection elements 350 are assembled to an assembly comprising, on the one hand, the substrate 100 in which are formed the plurality of first chips (or lower chips) and, on the other hand, the plurality of second chips 200 (or upper chips) (FIGS. 1F and 2F). The second chips are arranged opposite the first chips and are connected to one another by connection pads 120, 210.

The second chips 200 are assembled to the first chips by a technique of die-to-wafer (D2 W) type, in which the first chips are assembled to the second chips by hybrid bonding. A low chip-to-chip impedance is obtained.

Substrate 100 comprises a first surface 101 and a second surface 102. The connection pads 120 of the first chips are positioned on the first surface 101 of substrate 100. Connection landing areas 110, connected to the first chips, are also positioned on the first surface 101 of substrate 100. They are used to connect the first chips to an external element 500.

The second chips 200 comprise a first surface 201 (front side) and a second surface 202 (back side). Connection pads 210 are positioned on the first surface 201 of the second chips 200.

The second chips 200 have a thickness, for example, smaller than 60 μm, for example smaller than or equal to 30 μm (for example in the range from 20 to 30 μm).

This step of assembly of interconnection elements 350 on the connection areas 110 of substrate 100 is carried out by thermocompression (FIGS. 1F, 2F).

The thermocompression is, for example, carried out in the presence of ultrasounds. This enables to decrease the temperature and/or the pressure during this step.

During the thermocompression stage, the temperature is, for example, in the range from 90 to 170° C. The temperature is, for example, 150° C. The temperature is selected so as not to melt the other materials, and in particular the solder alloy.

The pressure is, for example, in the range from 0.2 N to 0.4 N per interconnection element 350.

At the end of the thermocompression step, thermocompressed bonds are formed between connection areas 110 and interconnection elements 350.

The thermocompressed bonds are obtained by atomic diffusion of the atoms present at the interfaces. The thermocompressed bonds form strong and durable joints without requiring adhesives or solvents.

When copper pillar 352 is covered by gold layer 353, the thermocompressed bond is a copper-to-gold bond (FIG. 1G).

When copper pillar 352 is not covered by gold layer 353, the thermocompressed bond is a copper-to-copper bond (FIG. 2G).

The thermocompressed bond does not comprise any element which is conventionally found in a seed layer (for example it is titanium-free), since the pillars are manufactured from their free end to their base, then assembled to the conductive landing areas 110 of substrate 100, unlike prior art methods for which the pillars are manufactured on the conductive landing areas from their base (as disclosed in prior art).

The obtained interconnection elements 350 are coplanar. Their upper surfaces are at the same height as the first surface 101 of substrate 100.

During step e), support substrate 310 and separation layer 320 are removed (FIGS. 1H, 2H). The separation step is carried out, for example, by applying an ultraviolet radiation or a thermal treatment to separation layer 320 to decrease its adhesive properties.

An assembly comprising a substrate 100 in which are formed first chips is thus obtained, second chips 200 being assembled to the first chips, for example by hybrid bonding.

The interconnection elements are assembled on conductive landing areas 110 positioned on substrate 100 and coupled to the first chips, by means of a copper-to-copper or copper-to-gold thermocompressed bond.

The interconnection elements may be positioned less than 250 μm away, preferably less than 100 μm away, and even more preferably less than 50 μm away, from the edge of the second chips 200. They are, for example, at a 30-μm distance from the edges of the second chips 200.

At the end of step e), the thermocompressed interconnection elements 350 successively comprise from the thermocompressed bond: optionally a gold layer 353, a copper pillar 352, a solder layer 351, and a seed layer 330.

So-called reflow step f) enables to melt solder layer 351 and seed layer 330 to form solder pads 354 having their final shape for the assembly with external element 500.

At the end of step f), the thermocompressed interconnection elements successively comprise from the thermocompressed bond: optionally a gold layer 353, a copper pillar 352, a solder layer 353, and a solder pad 354.

An intermetallic layer, resulting from the diffusion between layers of different materials, may optionally be present according to the nature of the involved layers.

After the implementation of these different steps, a step of cutting of substrate 100 may be carried out to form singulated electronic devices 1000. The cutting step may be carried out by means of a saw. This step is not shown in the drawings since, for readability reasons, a single first chip and a single second chip are shown in the drawings.

Each electronic device 1000 comprises at least a first chip and a second chip, as well as interconnection elements 350.

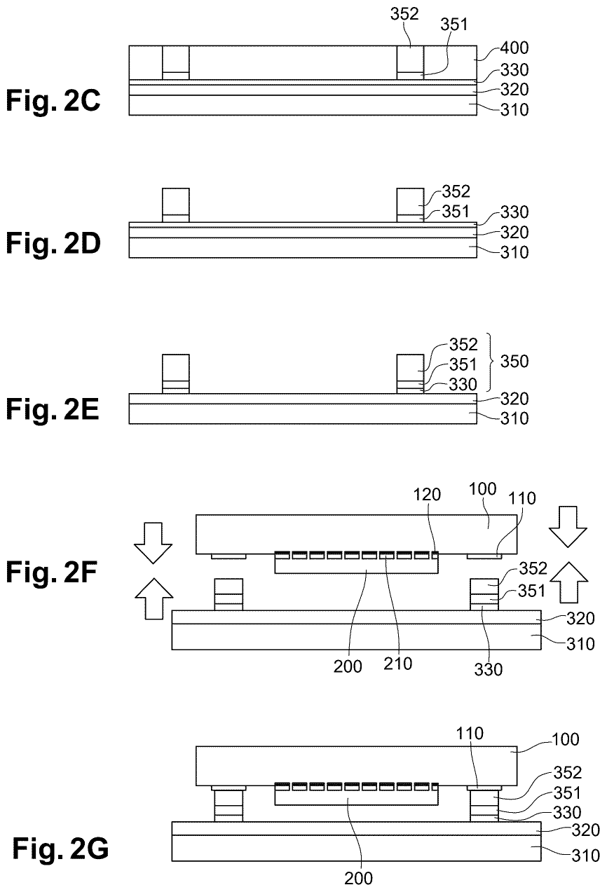

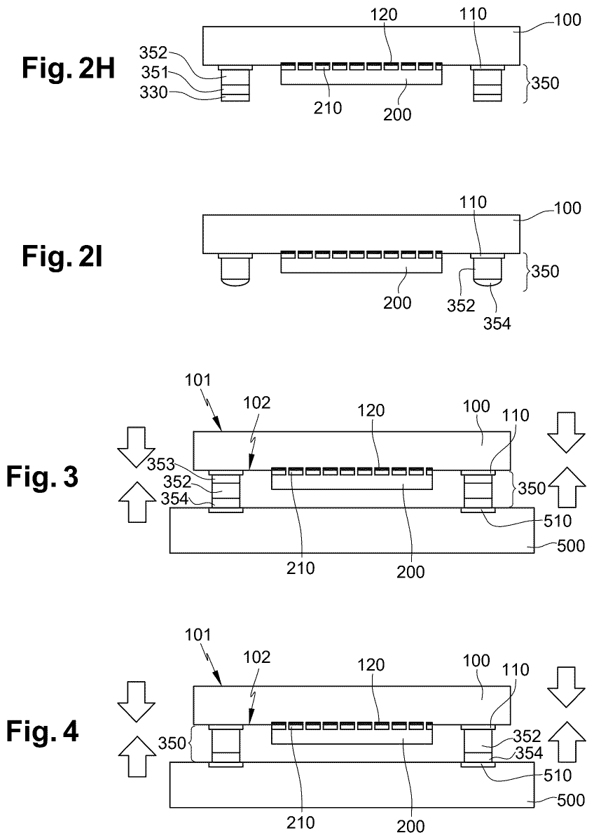

Such a device may then be assembled with an external element 500, such as a printed circuit board (PCB) or a laminated substrate (FIGS. 3 and 4).

It may be assembled by the solder bumping technique.

In particular, the method of assembling the device to an external element 500 comprises a step during which the interconnection elements 350 are aligned and brought into contact with the connection pads 510 of device 500, and a step, for example of soldering, during which the interconnects are bonded to the connection landing areas 510. The soldering ensures the electrical and mechanical contact between the device and the external element. It may be carried out either by adding additional solder paste or with a soldering flux which deoxidizes and holds the device during the step of reflow of solder pads 354. The assembly step may be carried out at a temperature in the range from 230° C. to 280° C., for example at 260° C.

A layer of electrically-insulating polymer (referred to as an “underfill”) may then be positioned between external element 500 and electronic device 1000. This coating layer is, for example, an epoxy layer. It is injected after the transfer of electronic device 1000 onto external element 500 by capillary action.

A molding step may then be carried out to form a package around the second chip 200.

The electronic device may be an analog memory device. It may be used in systems requiring a high number of inputs/outputs (I/O). It is of particular interest for the automotive field (especially for a microcontroller unit (MCU)) or for personal (such as “consumer”) objects.

Various embodiments and variants have been described. Those skilled in the art will understand that certain features of these various embodiments and variants may be combined, and other variants will occur to those skilled in the art.

Finally, the practical implementation of the described embodiments and variants is within the abilities of those skilled in the art based on the functional indications given hereabove.

1. A method of manufacturing electronic devices, comprising the following steps:
a) forming a resin layer having openings on a temporary substrate comprising a support substrate successively covered by a separation layer and by a seed layer;
b) forming interconnection elements by successively depositing a solder layer, a copper pillar, and optionally a gold layer through the openings of the resin layer;
c) removing the resin and etching the portion of the seed layer not covered by the interconnection elements;
d) assembling the interconnection elements to an assembly comprising a substrate in which are formed first chips and second chips assembled to the first chips using hybrid bonding, wherein the interconnection elements are assembled by thermocompression onto conductive landing areas positioned on the substrate and coupled to the first chips; and
e) removing the support substrate and the separation layer.

2. The method according to claim 1, further comprising, after step e), carrying out a thermal treatment to melt the solder layer and the seed layer and form solder pads.

3. The method according to claim 1, wherein the support substrate is made of glass or of metal.

4. The method according to claim 1, wherein the separation layer is made of an adhesive material sensitive to temperature or to an ultraviolet radiation.

5. The method according to claim 1, wherein the interconnection elements are positioned less than 250 μm away from the edge of the second chips.

6. The method according to claim 1, wherein the thermocompression step is carried out in the presence of ultrasounds.

7. The method according to claim 1, further comprising, after step f), cutting the substrate to form individualized electronic devices.

8. An electronic device, comprising:
a substrate including first chips and second chips assembled to the first chips by hybrid bonding;
interconnection elements assembled on conductive landing areas positioned on the substrate and coupled to the first chips by a thermocompressed bond comprising one of a copper-to-copper bond or a copper-to-gold bond;
wherein the interconnection elements successively comprise from the thermocompressed bond: optionally a gold layer, a copper pillar, and a solder pad;
wherein the interconnection elements are positioned less than 250 μm away from the edge of the second chips.

9. The electronic device according to claim 8, wherein the height of the interconnection elements is in the range from 60 to 80 μm and the diameter of the interconnection elements is in the range from 30 to 50 μm.

10. An assembly, comprising:
the electronic device of claim 8; and
an external device comprising one of a printed circuit board or a laminated substrate, comprising connection landing areas, interconnection elements being assembled to the connection landing areas.

11. A method of manufacturing the assembly of claim 10, the method comprising a step during which the interconnection elements are assembled to the connection landing areas of the external device using a solder steep.
